(19) United States
(12) Patent Application Publication
(10) Pub. No.: US 2016/0079375 A1
(43) Pub. Date: Mar. 17, 2016

(54) SEMICONDUCTOR DEVICE AND METHOD FOR MANUFACTURING SAME

(71) Applicant: Kabushiki Kaisha Toshiba, Tokyo (JP)

(72) Inventor: Yoshitaka Yamazaki, Nomi (JP)

(21) Appl. No.: 14/639,362

(22) Filed: Mar. 5, 2015

(30) Foreign Application Priority Data
Sep. 16, 2014 (JP) 2014-187929

(51) Int. Cl. H01L 29/40; H01L 29/78; H01L 29/739; H01L 29/423; H01L 29/06; H01L 23/528; H01L 21/02; H01L 29/66

(52) U.S. Cl. CPC H01L 29/407; H01L 21/02164; H01L 21/02271; H01L 29/7813; H01L 29/66734; H01L 29/401; H01L 29/4236; H01L 29/0696; H01L 23/528; H01L 29/7811; H01L 29/66348; H01L 29/7397

(57) ABSTRACT

According to one embodiment, the electrodes are provided in the first semiconductor layer and extend in a first direction. The gate electrodes are provided on the electrodes and extend in the first direction. The interconnection is provided outside ends in the first direction of the gate electrodes, extends in a second direction crossing the first direction, and is commonly connected to the electrodes. The gate contacts are provided on the gate electrodes and connected to the gate electrodes.

### CROSS-REFERENCE TO RELATED APPLICATION

This application is based upon and claims the benefit of priority from Japanese Patent Application No. 2014-187929, filed on Sep. 16, 2014; the entire contents of which are incorporated herein by reference.

### FIELD

Embodiments relate to a semiconductor device and a method for manufacturing the same.

### BACKGROUND

There has been proposed a device having a MOSFET (metal-oxide-semiconductor field effect transistor) structure of the trench gate type in which a field plate electrode is provided below the gate electrode via an interlayer insulating film.

In this structure, the field plate electrode and the gate electrode are provided in the trench. This requires a structure for extracting the field plate electrode and the gate electrode upward above the trench in order to connect them to an external circuit.

### BRIEF DESCRIPTION OF THE DRAWINGS

FIG. 1 is a schematic plan view of a semiconductor device of an embodiment;

FIG. 2 is a schematic plan view of the semiconductor device of the embodiment;

FIG. 3A is a schematic plan view of the semiconductor device of the embodiment, and FIG. 3B is a sectional view taken along line A-A in FIG. 3A;

FIG. 4A is a schematic plan view of the semiconductor device of the embodiment, and FIG. 4B is a sectional view taken along line F-F in FIG. 4B;

FIG. 5 is a sectional view taken along line B-B in FIG. 4B;

FIG. 6 is a sectional view taken along line C-C in FIG. 4B;

FIG. 7 is a sectional view taken along line D-D in FIG. 4B;

FIG. 8 is a sectional view taken along line E-E in FIG. 4B;

FIGS. 9 to 15B are schematic views showing a method for manufacturing the semiconductor device of the embodiment; and

FIGS. 16A to 18B are schematic views showing a method for manufacturing a semiconductor device of a reference example.

### DETAILED DESCRIPTION

According to one embodiment, a semiconductor device includes a semiconductor layer, a plurality of electrodes, an insulating film, a plurality of gate electrodes, a gate insulating film, a first interlayer insulating film, an interconnection, a second interlayer insulating film, and a plurality of gate contacts. The semiconductor layer includes a first semiconductor layer of a first conductivity type, a second semiconductor layer of a second conductivity type provided on the first semiconductor layer, and a third semiconductor layer of the first conductivity type provided on the second semiconductor layer. The plurality of electrodes are provided in the first semiconductor layer and extend in a first direction. The insulating film is provided between the electrodes and the first semiconductor layer. The plurality of gate electrodes are provided on the electrodes, opposed to the second semiconductor layer and the third semiconductor layer, and extend in the first direction. The gate insulating film is provided between the gate electrodes and the second semiconductor layer, and between the gate electrodes and the third semiconductor layer. The first interlayer insulating film is provided between the electrodes and the gate electrodes. The interconnection is provided outside ends in the first direction of the gate electrodes, extends in a second direction crossing the first direction, and is commonly connected to the electrodes. The second interlayer insulating film is provided between the ends of the gate electrodes and the interconnection. The plurality of gate contacts are provided on the gate electrodes and connected to the gate electrodes.

Embodiments will now be described with reference to the drawings. In the drawings, like elements are labeled with like reference numerals.

The following embodiments are described assuming that the first conductivity type is n-type and the second conductivity type is p-type. However, the first conductivity type may be p-type, and the second conductivity type may be n-type. Silicon is used as the semiconductor. Alternatively, semiconductors other than silicon (e.g., a compound semiconductor such as SiC and GaN) may be used.

The semiconductor device of the embodiments is a vertical device in which the current path is formed in the vertical direction connecting a first electrode and a second electrode. The first electrode is provided on one surface side of a semiconductor layer (or substrate). The second electrode is provided on the other surface side.

In the following embodiments, the semiconductor device has a MOSFET (metal-oxide-semiconductor field effect transistor) structure as an example. However, the semiconductor device may have an IGBT (insulated gate bipolar transistor) structure. In the case of IGBT, it is sufficient to replace the N⁺-type drain layer by a P⁺-type collector layer.

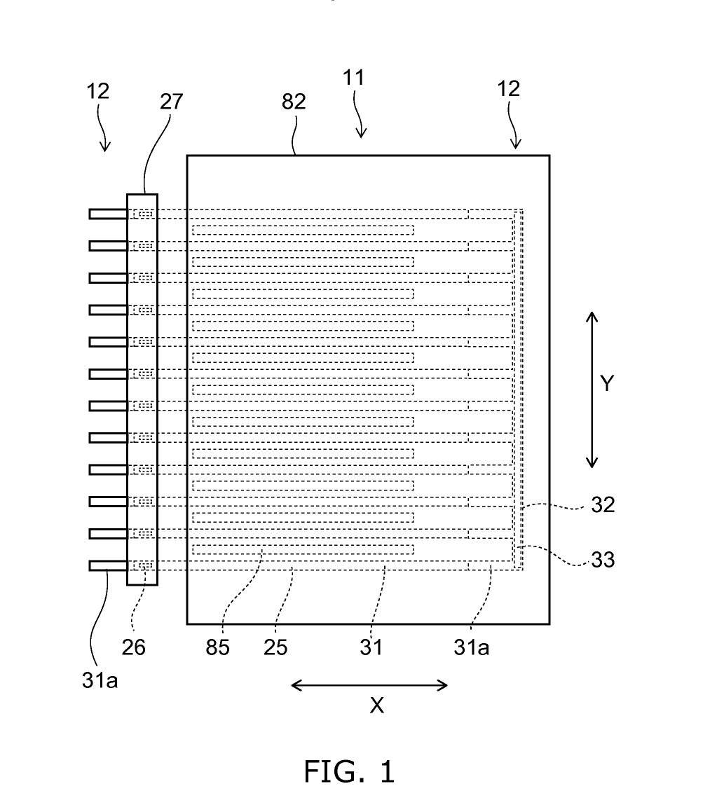

FIG. 1 is a schematic plan view of a semiconductor device of an embodiment.

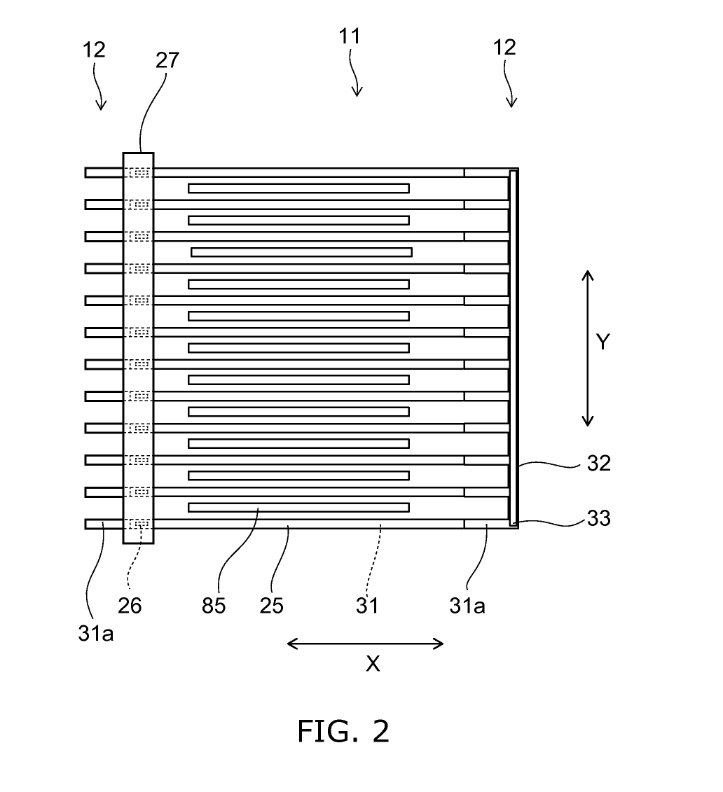

FIG. 2 is a schematic plan view in which the source electrode 82 is removed in the plan view of FIG. 1.

Two directions crossing in the plane parallel to the surface of the semiconductor layer (or substrate) is referred to as first direction (X-direction) and second direction (Y-direction). According to the embodiment, the first direction (X-direction) and the second direction (Y-direction) are orthogonal.

The semiconductor device of the embodiment includes a plurality of gate electrodes 25 extending in the first direction (X-direction). The plurality of gate electrodes 25 are arranged in the second direction (Y-direction) orthogonal to the first direction (X-direction).

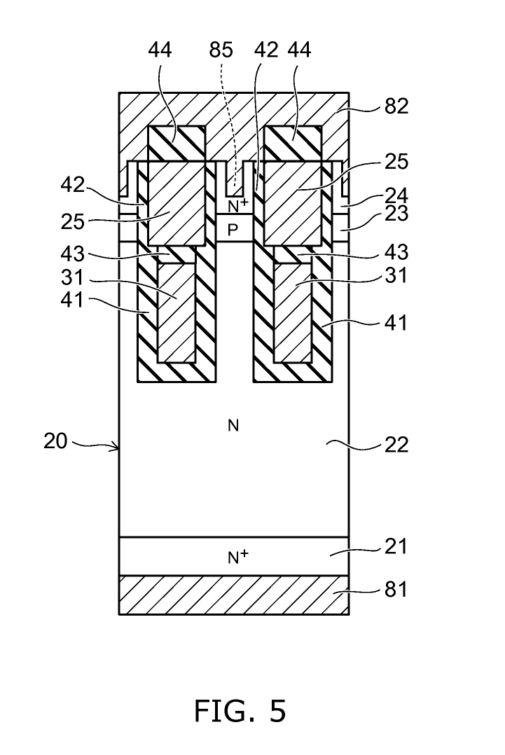

A trench contact part 85 of a source layer 24 (shown in FIG. 5) is provided between the gate electrodes 25 adjacent in the Y-direction. The trench contact part 85 extends in the X-direction. The gate electrodes 25 and the trench contact parts 85 are arranged alternately in the Y-direction.

As described later, a field plate electrode 31 is provided below the gate electrode 25 via an interlayer insulating film. The field plate electrode 31 extends below the gate electrode 25 in the same X-direction as the gate electrode 25. The X-direction length of the field plate electrode 31 is longer than the X-direction length of the gate electrode 25.

In plan view shown in FIGS. 1 and 2, both X-direction end parts 31a of the field plate electrode 31 protrude farther in the X-direction than both X-direction end parts of the gate electrode 25.

The trench contact part 85 of the source layer is formed in the cell region 11. A field plate interconnection 32 extending in the Y-direction is provided in the terminal region 12 outside the cell region 11 in the X-direction. The field plate interconnection 32 is provided outside the end of the gate electrode 25 in the X-direction.

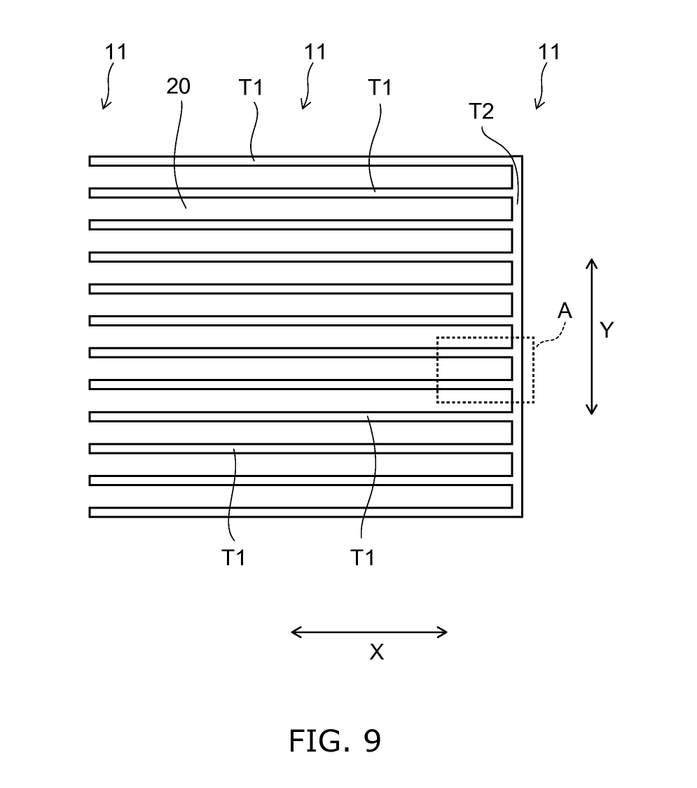

The field plate interconnection 32 is placed at one X-direction end of the field plate electrode 31. As described later with reference to FIG. 9, a plurality of first trenches T1 are formed in the semiconductor layer. The plurality of first trenches T1 extend in the X-direction and are arranged in the Y-direction.

A second trench T2 extending in the Y-direction is formed at one X-direction end of the first trench T1. The first trench T1 and the second trench T2 are simultaneously formed by e.g. RIE (reactive ion etching) technique. The first trench T1 and the second trench T2 are connected.

The field plate electrode 31 and the field plate interconnection 32 are integrally formed from the same material in the first trench T1 and the second trench T2. The field plate interconnection 32 is commonly connected to a plurality of field plate electrodes 31 at one X-direction end of the field plate electrodes 31.

The X-direction end of the gate electrode 25 is located in the first trench T1, and does not extend to the second trench T2. That is, the X-direction length of the gate electrode 25 is shorter than the X-direction length of the first trench T1.

A field plate contact 33 is provided on the field plate interconnection 32 connected to one X-direction end (right end in FIGS. 1 and 2) of the field plate electrode 31. The field plate contact 33 extends in the Y-direction and is connected to the field plate interconnection 32.

A gate contact 26 is provided at one X-direction end part (left end part in FIGS. 1 and 2) of each gate electrode 25. The gate contact 26 is provided directly above the gate electrode 25 and connected to the gate electrode 25.

A gate interconnection 27 extending in the Y-direction is provided on a plurality of gate contacts 26. The upper end of the gate contact 26 is connected to the gate interconnection 27. The gate interconnection 27 is commonly connected to a plurality of gate electrodes 25 through the gate contacts 26.

As shown in FIG. 1, a source electrode 82 is provided on the region including the trench contact part 85 of the source layer and on the field plate contact 33 in the cell region 11. The source layer 24 shown in FIG. 5 is connected to the source electrode 82 through the trench contact part 85. The field plate electrode 31 is connected to the source electrode 82 through the field plate interconnection 32 and the field plate contact 33.

In the field plate electrode 31, the field plate contact 33 is placed on the end part (right end part in FIGS. 1 and 2) opposite to the end part (left end part in FIGS. 1 and 2) on which the gate interconnection 27 is placed. Thus, a source electrode 82 having a large area can be easily laid out on the trench contact part 85 and on the field plate contact 33.

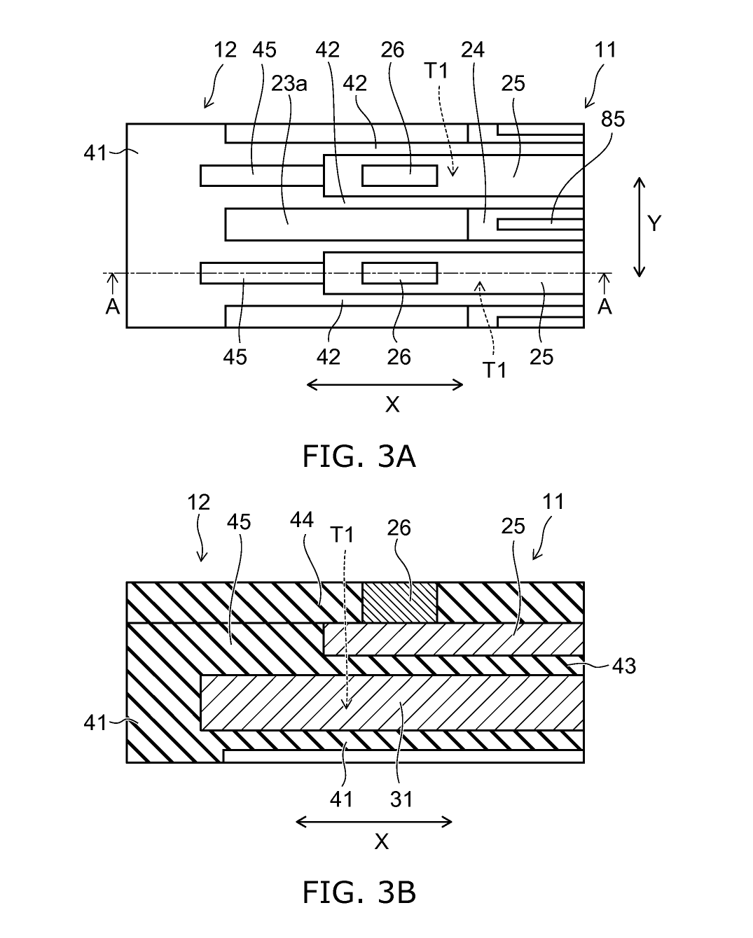

FIG. 3A is a schematic plan view on one (left in FIGS. 1 and 2) terminal region 12 side of the semiconductor device of the embodiment.

FIG. 3B is a sectional view taken along line A-A in FIG. 3A. In FIG. 3B, the elements below the trench are not shown. In FIG. 3A, the interlayer insulating film 44 shown in FIG. 3B is not shown.

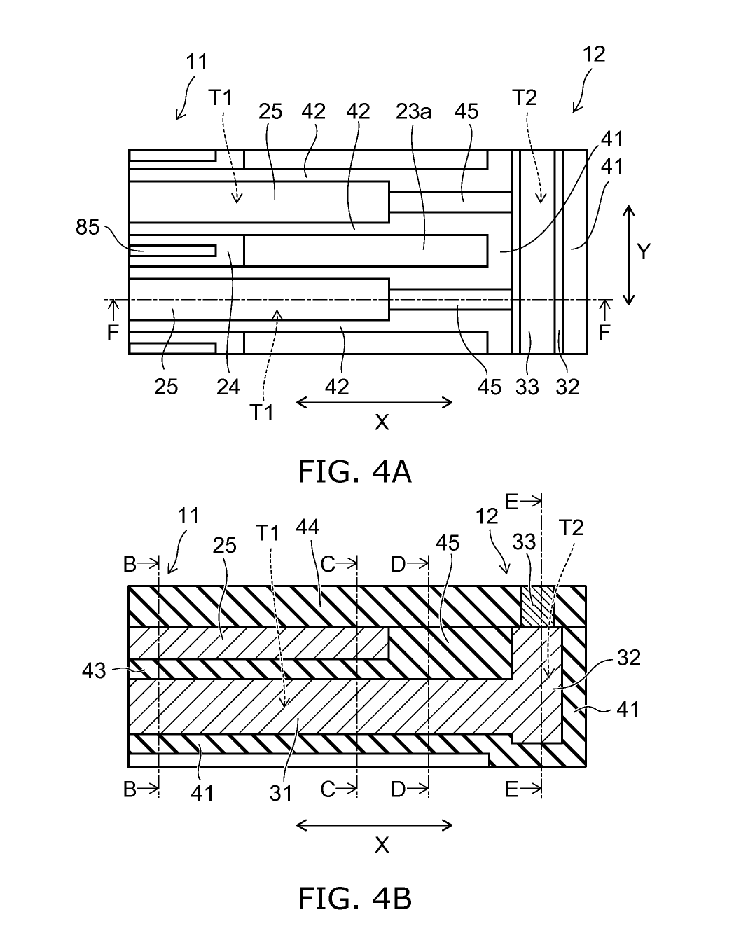

FIG. 4A is a schematic plan view on the other (right in FIGS. 1 and 2) terminal region 12 side of the semiconductor device of the embodiment.

FIG. 4B is a sectional view taken along line F-F in FIG. 4A. In FIG. 4B, the elements below the trench are not shown. In FIG. 4A, the interlayer insulating film 44 shown in FIG. 4B is not shown.

FIG. 5 is a sectional view taken along line B-B in FIG. 4B. FIG. 5 is a schematic sectional view of the cell region 11.

As shown in FIG. 5, in the cell region 11, a drain electrode 81 is provided as a first electrode on one surface side of the semiconductor layer 20. A source electrode 82 is provided as a second electrode on the other surface side.

The semiconductor layer 20 includes an N⁺-type drain layer 21 (fourth semiconductor layer), an N-type drift layer (first semiconductor layer) 22, a P-type base layer (second semiconductor layer) 23, and an N⁺-type source layer (third semiconductor layer) 24. The drain layer 21, the drift layer 22, the base layer 23, and the source layer 24 are each e.g. a silicon layer.

The drain layer 21 is provided on the drain electrode 81. The drain electrode 81 is in ohmic contact with the drain layer 21. The drift layer 22 is provided on the drain layer 21. The base layer 23 is provided on the drift layer 22. The source layer 24 is provided on the base layer 23. The N-type impurity concentration of the drain layer 21 and the N-type impurity concentration of the source layer 24 are higher than the N-type impurity concentration of the drift layer 22.

A field plate electrode 31 is provided in the drift layer 22. The field plate electrode 31 is e.g. a polycrystalline silicon film containing impurity for imparting conductivity.

A field insulating film 41 is provided between the field plate electrode 31 and the drift layer 22. That is, the field insulating film 41 is provided between the sidewall of the field plate electrode 31 and the drift layer 22 and between the bottom of the field plate electrode 31 and the drift layer 22. The field insulating film 41 is e.g. a silicon oxide film.

A plurality of gate electrodes 25 are provided on the field plate electrode 31 via an interlayer insulating film (first interlayer insulating film) 43. The gate electrodes 25 extending in the X-direction are independently separated in the Y-direction in the semiconductor layer 20. The gate electrodes 25 are not connected each other in the semiconductor layer 20. The gate electrode 25 is e.g. a polycrystalline silicon film containing impurity for imparting conductivity. The interlayer insulating film 43 is e.g. a silicon oxide film containing boron and phosphorus (BPSG, boro-phospho-silicate glass film).

A gate insulating film 42 is provided between the sidewall of the gate electrode 25 and the source layer 24 and between the sidewall of the gate electrode 25 and the base layer 23. The sidewall of the gate electrode 25 is opposed to the source layer 24 and the base layer 23 across the gate insulating film 42. The gate insulating film 42 is e.g. a silicon oxide film.

The film thickness of the gate insulating film 42 is thinner than the film thickness of the field insulating film 41 and the film thickness of the interlayer insulating film 43.

One end part (upper end part in FIG. 5) of the gate electrode 25 in the vertical direction connecting the drain electrode 81 and the source electrode 82 is located on the source layer 24 side of the boundary between the source layer 24 and the base layer 23. The other end part (lower end part in FIG. 5) of the gate electrode 25 in the vertical direction is located on the drift layer 22 side of the boundary between the base layer 23 and the drift layer 22.

The source electrode 82 is provided as a second electrode on the semiconductor layer 20 in the cell region 11. The source electrode 82 is in ohmic contact with the source layer 24 through the trench contact part 85. That is, the source electrode 82 is provided on the upper surface of the source layer 24, and provided also in the trench formed in the source layer 24. In the trench contact part 85, the source electrode 82 is in contact with the source layer 24 at the bottom and side surface of the trench.

This trench contact structure has a larger contact area between the source electrode 82 and the source layer 24 than the structure in which the source electrode 82 is in contact with only the upper surface of the source layer 24. This can reduce the contact resistance between the source electrode 82 and the source layer 24.

The interlayer insulating film 44 is provided between the gate electrode 25 and the source electrode 82. Thus, there is no electrical short circuit between the source electrode 82 and the gate electrode 25.

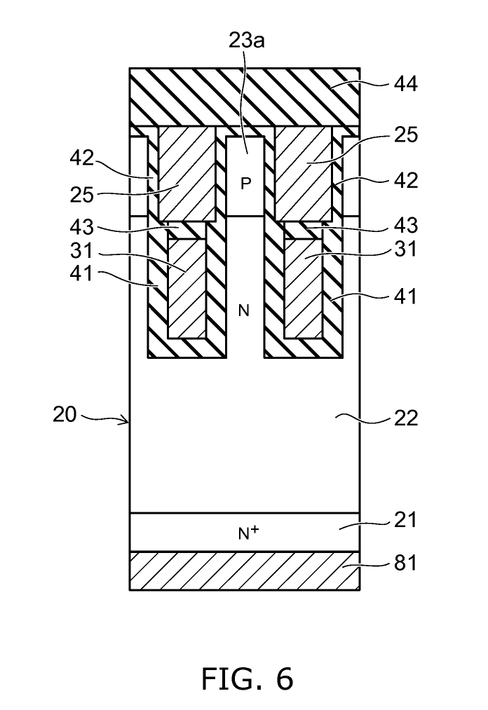

FIG. 6 is a sectional view taken along line C-C in FIG. 4B.

FIG. 6 is a schematic sectional view of the vicinity of the gate contact 26 in one end part of the gate electrode 25.

The source layer 24 is not provided in the semiconductor region between the end parts of the gate electrodes 25. The semiconductor region between the end parts of the gate electrodes 25 is a P-type semiconductor layer 23a having a P-type impurity concentration comparable to that of the P-type base layer 23. The end part of the gate electrode 25 is opposed to the P-type semiconductor layer 23a across the gate insulating film 42.

No source layer is provided also in the semiconductor region between the other end parts of the gate electrodes 25 shown in FIGS. 4A and 4B. As shown in FIG. 6, the other end part of the gate electrode 25 is opposed to the P-type semiconductor layer 23a across the gate insulating film 42.

As shown in FIG. 4B, an interlayer insulating film (second interlayer insulating film) 45 is provided between the X-direction end of the gate electrode 25 and the field plate interconnection 32.

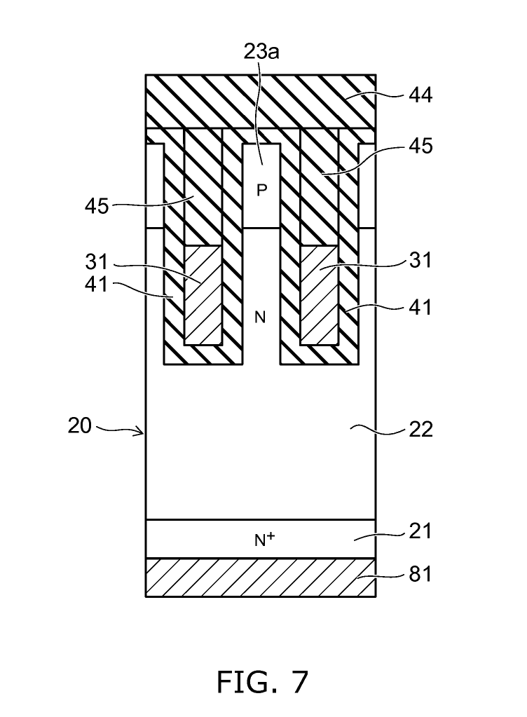

FIG. 7 is a sectional view taken along line D-D in FIG. 4B.

The interlayer insulating film 45 is formed simultaneously with the interlayer insulating film (first interlayer insulating film) 43 between the field plate electrode 31 and the gate electrode 25. The interlayer insulating film 45 is made of the same silicon oxide film (BPSG film) as the interlayer insulating film 43. The interlayer insulating film 45 is thicker than the interlayer insulating film 43.

As shown in FIG. 4B, the X-direction end of the field plate electrode 31 is integrally connected to the field plate interconnection 32.

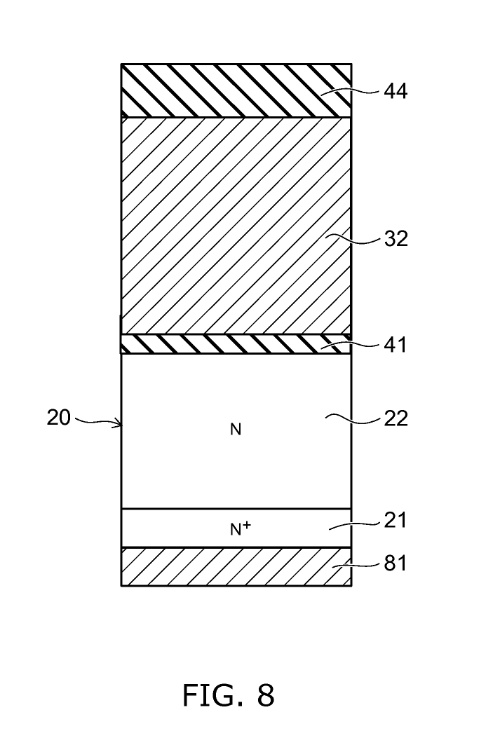

FIG. 8 is a sectional view taken along line E-E in FIG. 4B.

The height of the field plate interconnection 32 is higher than the height of the field plate electrode 31. The height referred to herein corresponds to the thickness in the stacking direction orthogonal to the X-direction and the Y-direction.

The field plate electrode 31 is provided on the lower (bottom) side of the first trench T1 extending in the X-direction. The upper surface of the field plate electrode 31 is located halfway in the depth direction of the first trench T1.

The upper surface of the field plate interconnection 32 provided in the second trench T2 extending in the Y-direction is located above (on the gate electrode 25 side of) the upper surface of the field plate electrode 31.

As shown in FIG. 4B, an interlayer insulating film 44 is provided on the gate electrode 25, on the interlayer insulating film 45, and on the field plate interconnection 32. The interlayer insulating film 44 is e.g. a silicon oxide film.

As shown in FIGS. 6 and 7, the interlayer insulating film 44 is provided also on the upper part (P-type semiconductor layer 23a) of the semiconductor layer between the gate electrodes 25 and on the upper part (P-type semiconductor layer 23a) of the semiconductor layer in the terminal region.

As shown in FIGS. 3A and 3B, a gate contact 26 is provided through the interlayer insulating film 44 on one X-direction end part of the gate electrode 25. As shown in FIGS. 1, 2, and 3A, a gate contact 26 is provided on each gate electrode 25.

A plurality of gate electrodes 25 are each electrically connected through the gate contact 26 to the common gate interconnection 27 shown in FIGS. 1 and 2. The gate contact 26 and the gate interconnection 27 are provided above the semiconductor layer 20.

As shown in FIGS. 4A and 4B, a field plate contact 33 is provided through the interlayer insulating film 44 on the field plate interconnection 32 placed on the other X-direction end part side of the gate electrode 25. As shown in FIGS. 1, 2, and 4A, the field plate contact 33 extends in the Y-direction. The field plate interconnection 32 is provided in the semiconductor layer 20, the field plate contact 33 is provided above the semiconductor layer 20.

The field plate electrode 31 is electrically connected to the source electrode 82 through the field plate interconnection 32 and the field plate contact 33.

As shown in FIGS. 1 and 5, the source layer is electrically connected to the source electrode 82 through the trench contact part 85.

In the cell region shown in FIG. 5, a potential difference is applied between the drain electrode 81 and the source electrode 82. In this state, a desired gate voltage is applied to the gate electrode 25. Then, an N-type channel (inversion layer) is induced in the region of the P-type base layer 23 opposed to the gate electrode 25. Thus, the semiconductor device is turned on. Accordingly, a current flows between the drain electrode 81 and the source electrode 82 through the N⁺-type source layer 24, the N-type channel, the N-type drift layer 22, and the N⁺-type drain layer 21.

The semiconductor device of the embodiment is e.g. an N-type MOSFET. Thus, the drain electrode 81 is applied with a relatively high potential, and the source electrode 82 is applied with a relatively low potential. The gate electrode 25 is applied with a positive potential lower than the drain potential.

The field plate electrode 31 provided below the gate electrode 25 cancels out space charge due to impurity of the drift layer 22. Thus, the electric field occurring in the drift layer 22 can be made nearly constant.

At switch-off time when no channel is induced in the P-type base layer 23, space charge (positive charge) may occur due to impurity contained in the drift layer 22. However, the space charge is canceled out with the negative charge induced at the surface of the field plate electrode 31. Thus, the drift layer 22 is widely depleted. Accordingly, the semiconductor device maintains high breakdown voltage.

Furthermore, the depletion layer is likely to extend in the drift layer 22. Thus, the impurity concentration of the drift layer 22 can be made higher than that in the case where the field plate electrode 31 is not provided. This can decrease the on-resistance.

According to the embodiment, the connection part of the field plate electrode 31 extending in the X-direction and the field plate interconnection 32 extending in the Y-direction is formed in a T-shape in plan view.

On the other hand, the gate electrode 25 is provided only in the first trench T1 extending in the X-direction, and not provided in the second trench T2 extending in the Y-direction. Thus, the gate electrode 25 includes no T-shaped part. Accordingly, there is no concern about the decrease of gate withstand capability at a corner part of the T-shaped part of the gate electrode 25.

In the semiconductor layer 20, the upper part provided between the gate electrodes 25 adjacent in the Y-direction extends in the X-direction. As shown in FIGS. 3A and 4A, an interlayer insulating film 41 is provided at the corner part of the X-direction end of the upper part (P-type semiconductor layer 23a) of the semiconductor layer in the terminal region 12. The interlayer insulating film 41 has a thicker film thickness than the gate insulating film 42.

Next, a method for manufacturing the semiconductor device of the embodiment is described with reference to FIGS. 9 to 15B.

As shown in the plan view of FIG. 9, first trenches T1 and a second trench T2 are formed in the semiconductor layer 20. The first trenches T1 and the second trench T2 are simultaneously formed by RIE (reactive ion etching) technique using a mask, not shown.

A plurality of first trenches T1 extend in the X-direction and are arranged in the Y-direction. The second trench T2 is commonly connected to the plurality of first trenches T1 at one X-direction end of the plurality of first trenches T1.

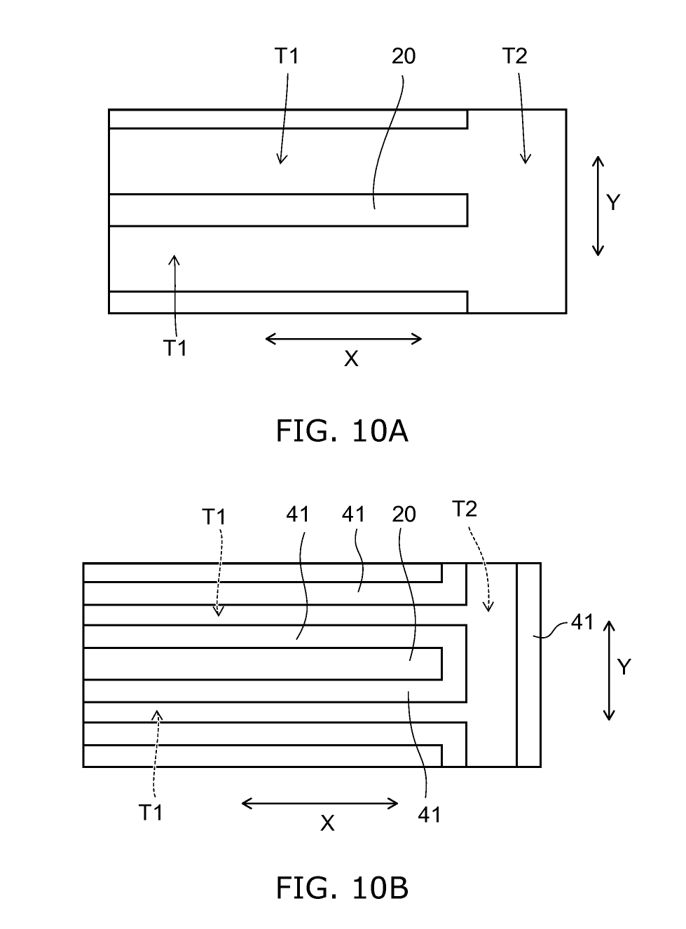

FIG. 10A is an enlarged plan view of part A in FIG. 9.

FIGS. 10B, 11A, 12A, 13A, 14A, and 15A are schematic plan views showing steps subsequent to FIG. 10A.

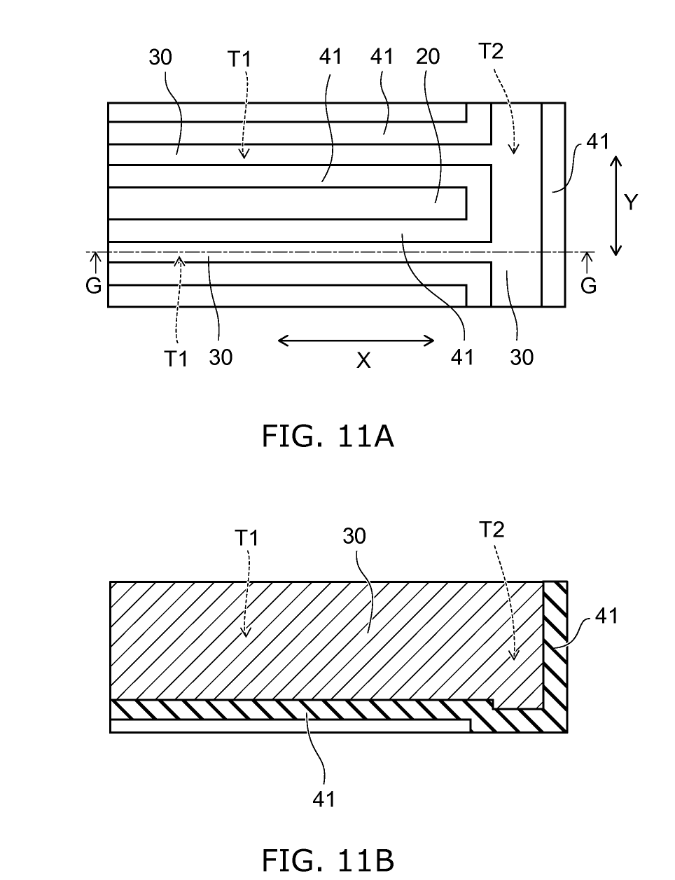

FIG. 11B is a sectional view taken along line G-G in FIG. 11A.

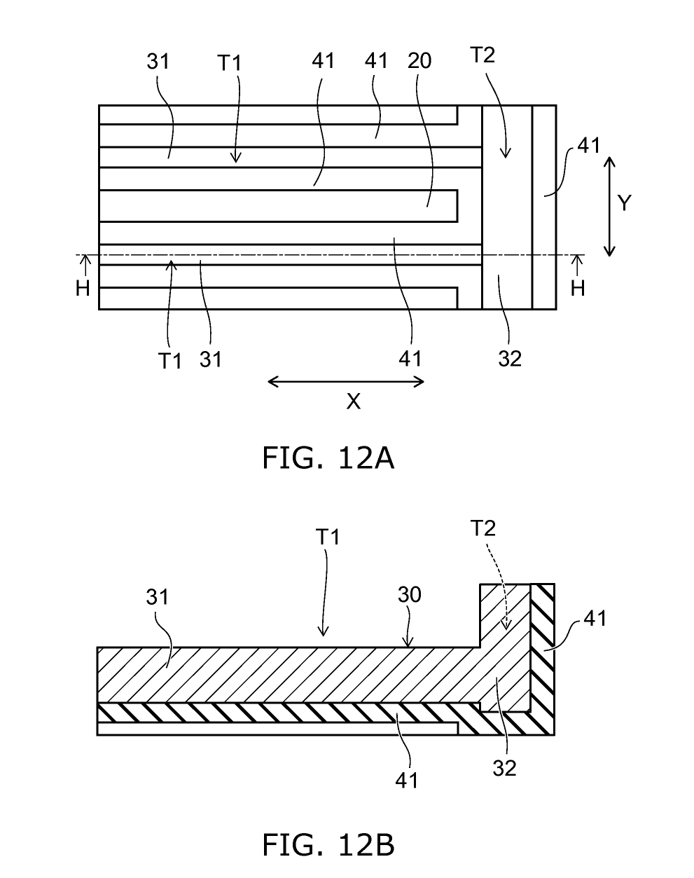

FIG. 12B is a sectional view taken along line H-H in FIG. 12A.

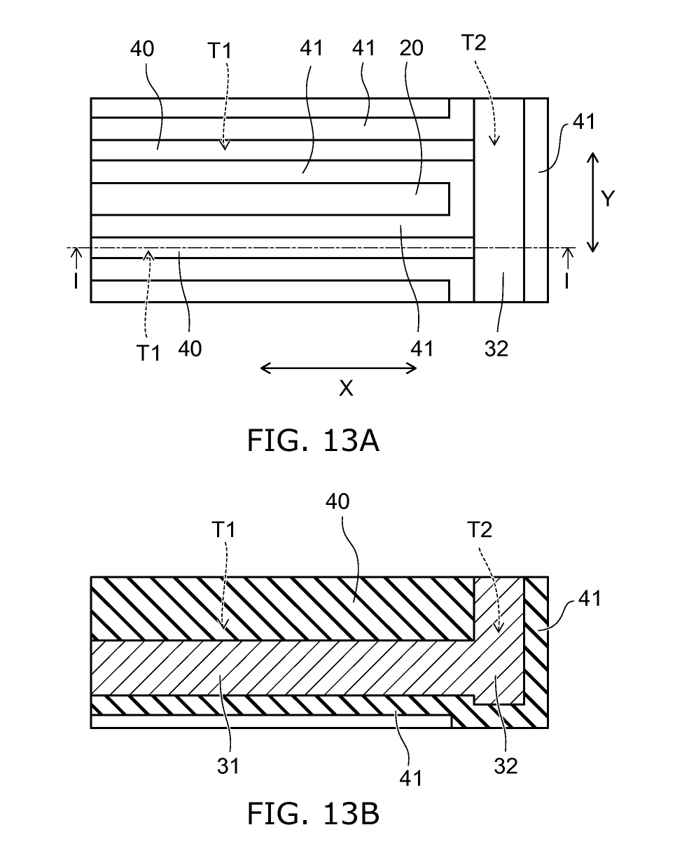

FIG. 13B is a sectional view taken along line I-I in FIG. 13A.

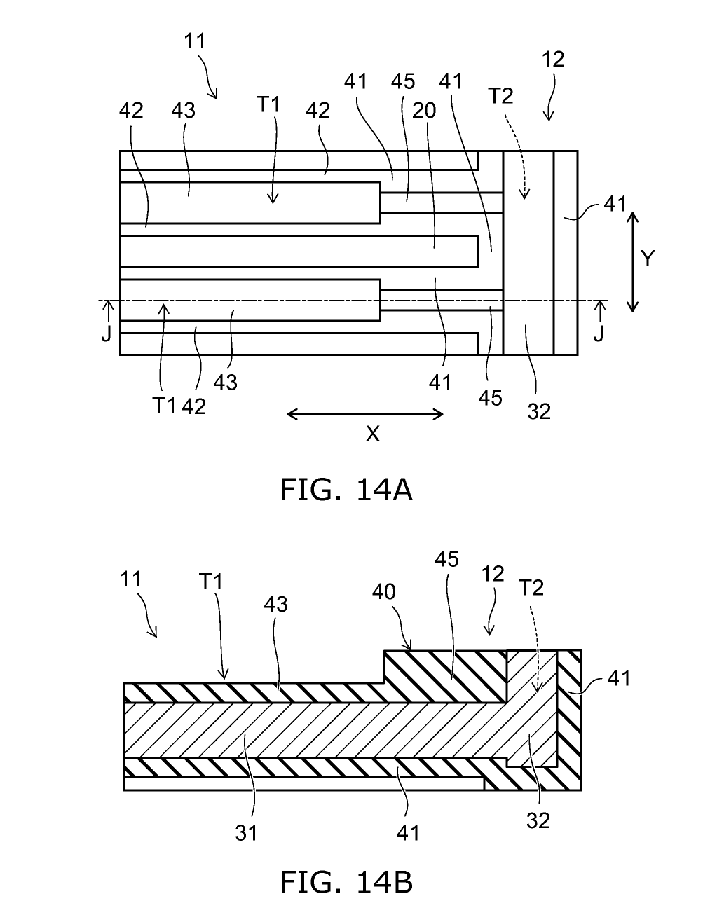

FIG. 14B is a sectional view taken along line J-J in FIG. 14A.

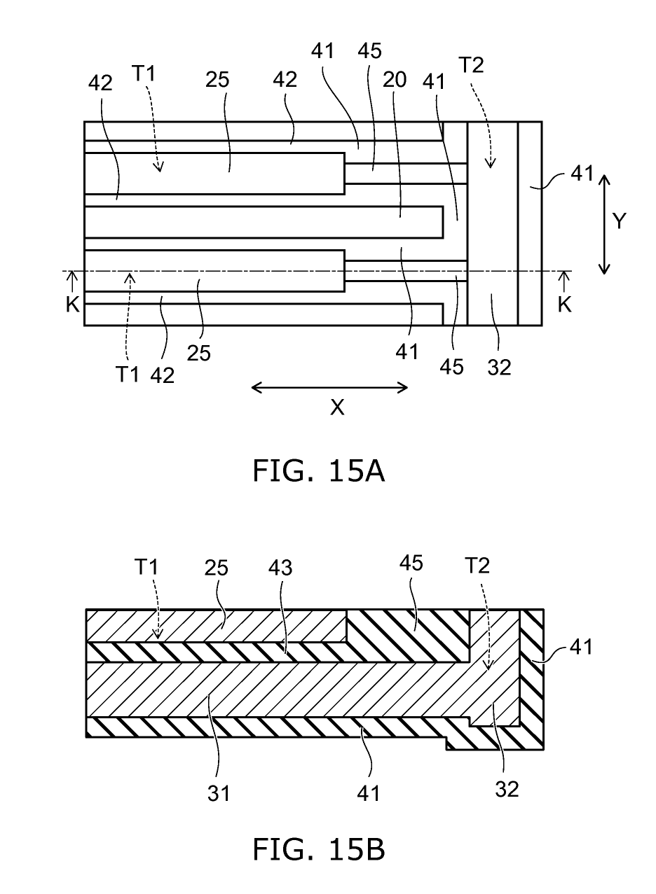

FIG. 15B is a sectional view taken along line K-K in FIG. 15A.

After forming the first trench T1 and the second trench T2, a field insulating film 41 is formed on the inner wall (bottom and sidewall) of the first trench T1 and the inner wall (bottom and sidewall) of the second trench T2 as shown in FIG. 10B. The field insulating film 41 is e.g. a silicon oxide film formed by thermal oxidation technique. The field insulating film 41 is a non-doped film containing substantially no impurity.

Next, as shown in FIGS. 11A and 11B, a field plate film 30 is embedded inside the field insulating film 41 in the first trench T1 and in the second trench T2. The field plate film 30 is e.g. a polycrystalline silicon film.

The field plate film 30 is formed in a T-shape in plan view near the boundary between the first trench T1 and the second trench T2.

After forming the field plate film 30 in the first trench T1 and in the second trench T2, the upper side of the field plate film 30 in the first trench T1 is removed by etching as shown in FIGS. 12A and 12B.

The field plate film 30 left in the first trench T1 constitutes the aforementioned field plate electrode 31. The field plate film 30 left in the second trench T2 constitutes the aforementioned field plate interconnection 32.

The upper surface height of the field plate interconnection 32 left in the second trench T2 is located at a higher position (trench opening end side) than the upper surface height of the field plate electrode 31 left in the first trench T1.

Next, as shown in FIGS. 13A and 13B, an interlayer insulating film 40 is formed on the field plate electrode 31 left in the first trench T1. The interlayer insulating film 40 is e.g. a silicon oxide film containing boron and phosphorus (BPSG film). The BPSG film is superior in embeddability and formed by CVD (chemical vapor deposition) technique.

As shown in FIG. 13B, the field plate interconnection 32 in the second trench T2 protrude farther upward (on the trench opening end side) than the field plate electrode 31 in the first trench T1. The interlayer insulating film 40 is adjacently in contact with the protruding field plate interconnection 32 in the second trench T2.

Next, as shown in FIGS. 14A and 14B, the upper side of the interlayer insulating film 40 in the cell region 11 farther from the second trench T2 than the portion adjacent to the field plate interconnection 32 in the second trench T2 is removed. An interlayer insulating film 43 is left on the field plate electrode 31 in the cell region 11. The interlayer insulating film 43 is thinner than the interlayer insulating film 45 adjacent to the field plate interconnection 32 in the second trench T2.

Furthermore, the field insulating film 41 is also etched by the etching of the interlayer insulating film 40 in the cell region 11 at this time. The field insulating film 41 is a silicon oxide-based film like the interlayer insulating film 40, and has been formed on the upper sidewall of the first trench T1. Thus, as shown in FIG. 14A, a silicon oxide film thinner than the field insulating film 41 is left as a gate insulating film 42 on the upper sidewall of the first trench T1 in the cell region 11.

The interlayer insulating film 45 in the terminal region 12 is left thicker than the interlayer insulating film 43 in the cell region 11. Thus, a field insulating film 41 thicker than the gate insulating film 42 in the cell region 11 is left on the sidewall of the first trench T1 in the terminal region 12.

Then, as shown in FIGS. 15A and 15B, a gate electrode 25 is embedded on the interlayer insulating film 43 left in the cell region 11 and in the region between the gate insulating films 42. The gate electrode 25 is e.g. a polycrystalline silicon film.

Subsequently, as shown in FIGS. 3B and 4B, an interlayer insulating film 44 is formed on the gate electrode 25, on the interlayer insulating film 45, and on the field plate interconnection 32. The interlayer insulating film 44 is e.g. a silicon oxide film.

Then, as shown in FIGS. 3A and 3B, a gate contact 26 is formed on one X-direction end part of each gate electrode 25. The gate contact 26 penetrates through the interlayer insulating film 44 to the gate electrode 25.

As shown in FIGS. 4A and 4B, a field plate contact 33 is formed on the field plate interconnection 32 in the second trench T2 on the other end part side of the gate electrode 25. The field plate contact 33 penetrates through the interlayer insulating film 44 to the field plate interconnection 32.

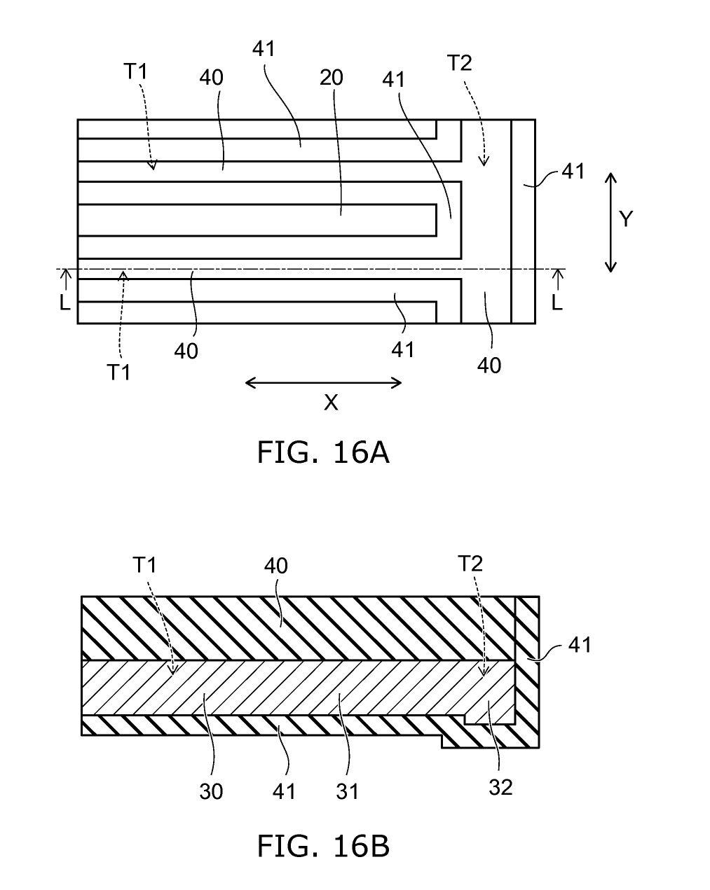

FIGS. 16A to 18B are schematic views showing a method for forming a field plate electrode 31 and a gate electrode 25 according to a reference example.

FIGS. 16A, 17A, and 18A are schematic plan views corresponding to part A in FIG. 9.

FIG. 16B is a sectional view taken along line L-L in FIG. 16A.

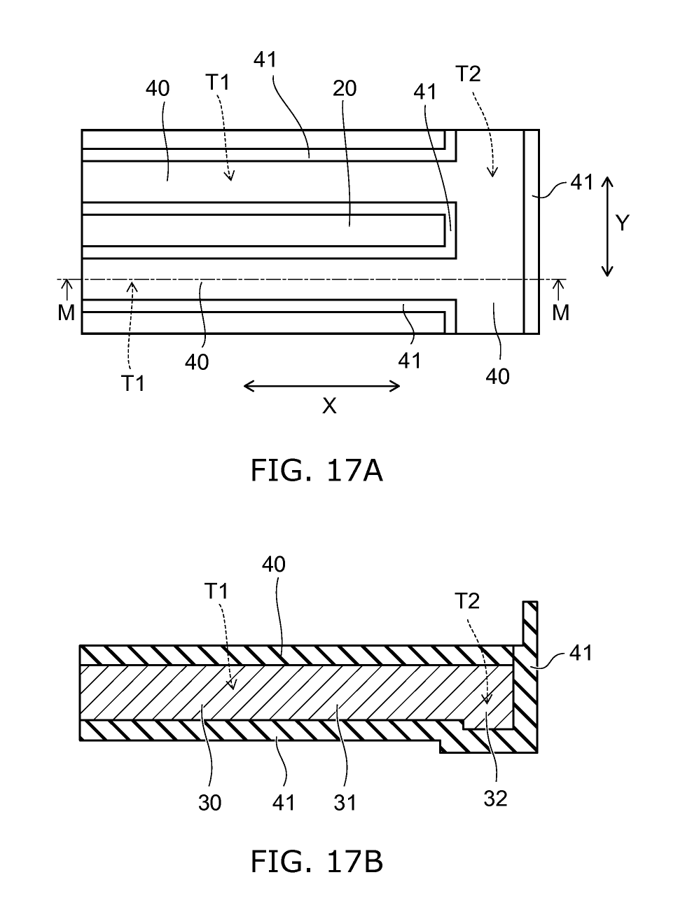

FIG. 17B is a sectional view taken along line M-M in FIG. 17A.

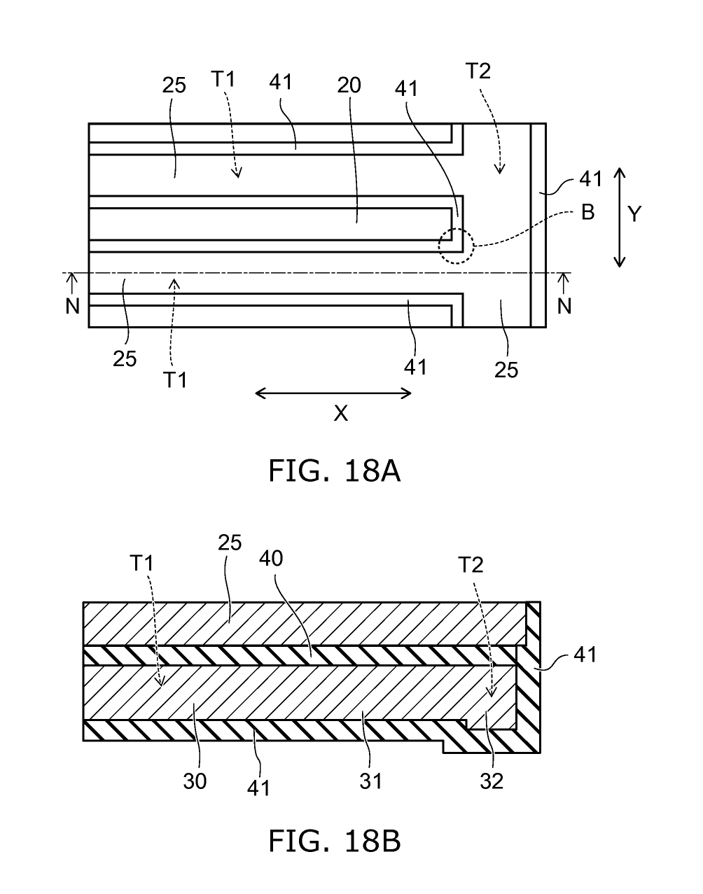

FIG. 18B is a sectional view taken along line N-N in FIG. 18A.

In the reference example, a field plate film 30 is embedded via a field insulating film 41 in the first trench T1 and in the second trench T2. Then, as shown in FIG. 16B, not only the field plate film 30 in the first trench T1 but also the field plate film 30 in the second trench T2 is set back by etching to halfway in the trench depth direction. After the etching, an interlayer insulating film 40 is embedded on the field plate film 30. The interlayer insulating film 40 is embedded in the upper part of the first trench T1 and the upper part of the second trench T2.

As shown in FIG. 17B, the interlayer insulating film 40 on the field plate film 30 is set back by etching to halfway in the trench depth direction.

The insulating film 41 formed on the upper sidewall of the first trench T1 is a silicon oxide-based film like the interlayer insulating film 40. Thus, in this etching of the interlayer insulating film 40, the insulating film 41 is also etched. Accordingly, as shown in FIG. 17A, the film thickness thereof becomes thinner than that before etching (FIG. 16A).

Furthermore, in the reference example, the interlayer insulating film 40 is formed also in the upper part of the second trench T2. The interlayer insulating film 40 in the upper part of the second trench T2 is also set back by etching. Thus, the film thickness of the insulating film 41 formed on the upper sidewall of the second trench T2 also becomes thinner by this etching.

Subsequently, as shown in FIGS. 18A and 18B, a gate electrode 25 is embedded in the upper part of the first trench T1 and the upper part of the second trench T2 formed by the removal of the upper side of the interlayer insulating film 40.

The gate electrode 25 is provided on the field plate film 30 via the interlayer insulating film 40. The stacked film of the field plate film 30, the interlayer insulating film 40, and the gate electrode 25 is provided in the first trench T1 extending in the X-direction and in the second trench T2 extending in the Y-direction.

Thus, the gate electrode 25 includes a portion formed in a T-shape near the boundary between the portion extending in the X-direction and the portion extending in the Y-direction.

According to the reference example, the insulating film 41 at the corner part (part B in FIG. 18A) of the T-shaped portion is thinned by etching during the etching of the interlayer insulating film 40 as described above. The corner part B of the T-shaped part of the gate electrode 25 is a site prone to electric field concentration. If the insulating film 41 formed at the corner part B is thin, there is concern about the decrease of gate withstand capability.

The insulating film of the corner part B may be thickened by performing e.g. a thermal oxidation process before forming the gate electrode 25. This improves the gate withstand capability, but increases the process load.

In contrast, according to the embodiment, as shown in FIGS. 15A and 15B, the gate electrode 25 is provided only in the first trench T1, and not provided in the second trench T2. Thus, the gate electrode 25 includes no T-shaped portion in plan view. Accordingly, there is no problem of the decrease of gate withstand capability in the T-shaped portion of the gate electrode 25.

As shown in FIG. 14B, the interlayer insulating film 45 adjacent to the field plate interconnection 32 in the second trench T2 is not etched, and not set back. Thus, as shown in FIG. 14A, a field insulating film 41 thicker than the gate insulating film 42 is left at the corner part of the T-shaped portion where the field plate electrode 31 is connected to the field plate interconnection 32. Accordingly, although the field plate films 31, 32 include a T-shaped portion, it does not decrease the withstand capability of the T-shaped portion. Furthermore, there is no need of a process for thickening the insulating film of the T-shaped portion of the field plate films 31, 32 after etching the interlayer insulating film 40.

As described above, the embodiment enables compatibility between high gate withstand capability and process load reduction (cost reduction).

Furthermore, as shown in FIGS. 3A, 4A, 6, and 7, the N⁺-type source layer 24 is not provided in the upper part of the semiconductor layer on the terminal region 12 side of the trench contact part 85 of the source layer 24, but the P-type semiconductor layer 23a is provided therein. The P-type impurity concentration of the P-type semiconductor layer 23a is comparable to the P-type impurity concentration of the P-type base layer 23. Thus, the P-type semiconductor layer 23a in the terminal region 12 has a breakdown voltage comparable to that of the P-type base layer 23 in the cell region 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a semiconductor layer including a first semiconductor layer of a first conductivity type, a second semiconductor layer of a second conductivity type provided on the first semiconductor layer, and a third semiconductor layer of the first conductivity type provided on the second semiconductor layer;
a plurality of electrodes provided in the first semiconductor layer and extending in a first direction;
an insulating film provided between the electrodes and the first semiconductor layer;
a plurality of gate electrodes provided on the electrodes, opposed to the second semiconductor layer and the third semiconductor layer, and extending in the first direction;
a gate insulating film provided between the gate electrodes and the second semiconductor layer, and between the gate electrodes and the third semiconductor layer;
a first interlayer insulating film provided between the electrodes and the gate electrodes;
an interconnection provided outside ends in the first direction of the gate electrodes, extending in a second direction crossing the first direction, and commonly connected to the electrodes;
a second interlayer insulating film provided between the ends of the gate electrodes and the interconnection; and
a plurality of gate contacts provided on the gate electrodes and connected to the gate electrodes.

2. The device according to claim 1, wherein a film thickness of the insulating film is thicker than a film thickness of the gate insulating film.

3. The device according to claim 1, wherein the gate electrodes extend in the first direction, and do not extend in the second direction.

4. The device according to claim 1, wherein a height of the interconnection is higher than heights of the electrodes.

5. The device according to claim 1, wherein the gate electrodes are independently separated in the semiconductor layer.

6. The device according to claim 5, wherein the gate contacts are provided above the semiconductor layer.

7. The device according to claim 6, further comprising:
a gate interconnection provided above the semiconductor layer, extending in the second direction, and commonly connected to the gate contacts.

8. The device according to claim 1, wherein the interconnection is provided in the semiconductor layer.

9. The device according to claim 1, further comprising:
a contact provided on the interconnection and connected to the interconnection.

10. The device according to claim 9, wherein the contact extends in the second direction.

11. The device according to claim 1, wherein the semiconductor layer includes a fourth semiconductor layer having an impurity concentration higher than an impurity concentration of the first semiconductor layer, and the first semiconductor layer is provided between the fourth semiconductor layer and the second semiconductor layer.

12. The device according to claim 11, further comprising:
a first electrode connected to the fourth semiconductor layer; and
a second electrode connected to the third semiconductor layer.

13. The device according to claim 12, wherein the electrodes are connected to the second electrode.

14. The device according to claim 12, further comprising:
a contact provided on the interconnection and connected to the interconnection,
wherein the electrodes are connected to the second electrode through the interconnection and the contact.

15. The device according to claim 1, wherein lengths in the first direction of the electrodes are longer than lengths in the first direction of the gate electrodes.

16. The device according to claim 1, wherein the gate contacts are located at one end in the first direction, and the interconnection is located at the other end in the first direction.

17. A method for manufacturing a semiconductor device, comprising:
forming a plurality of first trenches and a second trench in a semiconductor layer, the first trenches extending in a first direction, and the second trench being connected to ends in the first direction of the first trenches and extending in a second direction crossing the first direction;
forming an insulating film on inner walls of the first trenches and an inner wall of the second trench;
forming a first film inside the insulating film in the first trenches and in the second trench;
removing an upper side of the first film in the first trenches;
forming an interlayer insulating film on the first film left in the first trenches so that the interlayer insulating film is adjacent to the first film in the second trench;
removing an upper side of a second portion of the interlayer insulating film in a cell region farther from the second trench than a first portion of the interlayer insulating film adjacent to the first film in the second trench, leaving the second portion thinner than the first portion in the cell region, and leaving the first portion thicker than the second portion so that the first portion is adjacent to the first film in the second trench;
forming a gate electrode on the second portion of the interlayer insulating film left in the cell region; and
forming a gate contact on the gate electrode.

18. The method according to claim 17, further comprising:
forming a contact on the first film in the second trench.

19. The method according to claim 17, wherein a silicon oxide film containing at least one of boron and phosphorus is formed as the interlayer insulating film by chemical vapor deposition (CVD) technique.

20. The method according to claim 17, wherein the first film is a silicon film.
